(19) United States
(12) Patent Application Publication
(10) Pub. No.: US 2007/0046312 A1
(43) Pub. Date: Mar. 1, 2007

(54) Printed circuit board for real-time clock IC and manufacturing method for printed circuit board for real-time clock IC

(75) Inventor: Yasuo Funato, Saitama-shi (JP)

Correspondence Address: PILLSBURY WINTHROP SHAW PITTMAN, LLP, P.O. BOX 10500, MCLEAN, VA, 22102, US

(73) Assignee: KABUSHIKI KAISHA TOSHIBA, Tokyo (JP)

(21) Appl. No.: 11/506,905

(22) Filed: Aug. 21, 2006

(30) Foreign Application Priority Data
Aug. 24, 2005 (JP) 2005-243217

(51) Int. Cl. G01R 31/26

(52) U.S. Cl. 324/765

(57) ABSTRACT

According to one embodiment, a printed circuit board for a real-time clock IC includes a plurality of wiring layers sequentially laminated to form one substrata and including at least one layer which forms an oscillator circuit pattern having a crystal oscillator generating a reference signal and an oscillation stabilizing portion which stabilizes and oscillates the reference signal and adjusts the oscillation frequency to a target frequency, and a power supply layer arranged in at least one of a position between the plurality of wiring layers and front and rear surfaces of the substrate, and forming a power supply circuit pattern which supplies electric power to a circuit on the substrate and removing a portion of the power supply circuit pattern which has width not smaller than width of the oscillator circuit pattern in a portion of the power supply circuit pattern which overlaps with the oscillator circuit pattern.

### CROSS-REFERENCE TO RELATED APPLICATIONS

This application is based upon and claims the benefit of priority from Japanese Patent Application No. 2005-243217, filed Aug. 24, 2005, the entire contents of which are incorporated herein by reference.

### BACKGROUND

1. Field

One embodiment of the invention relates to a printed circuit board for a real-time clock IC used in an electronic equipment such as a key-telephone equipment, for example, and a manufacturing method for the printed circuit board for the real-time clock IC.

2. Description of the Related Art

Generally, a real time clock IC is used in an electronic equipment such as a key-telephone equipment to realize a real-time clock function. An oscillation frequency of 32.768 KHz is generally used in the real time clock IC and a tuning fork type crystal is used as a crystal oscillator which oscillates at the above frequency.

In the above electronic equipment, the specification of an error of ±1 minute for each month is required for the real time clock function as one example. In order to satisfy the above required specification, the precision of the oscillation frequency of ±23 ppm is required. However, a variation in the center value in a tuning fork type crystal is large and an oscillation frequency change due to temperatures occurs. Therefore, generally, one of capacitors connected to both ends of the crystal oscillator is formed as a trimmer capacitor and the oscillation frequency is adjusted at the time of product shipment.

The capacitances of the capacitors connected to both ends of the crystal oscillator are generally as small values as before and behind 10 pf(s). Therefore, since the oscillation frequency is influenced by stray capacitance or the like due to a pattern of the printed circuit board, the capacitance of the capacitor on the fixed-capacitance side is adjusted for each type so as to extend the adjusting frequency range by the trimmer capacitor into the center value of the target oscillation frequency.

However, recently, the printed circuit board is formed into a multiple layered form with an increase in the density and a gap between the crystal oscillator circuit pattern layer and the power supply layer or ground layer becomes smaller, it cause to increase the stray capacitance including at around crystal circuit. In the worst case, there occurs a problem that the adjusting range cannot be set into the target range of the center value of the oscillation frequency on the trimmer capacitor side even if the capacitance on the fixed-capacitance side is set to 0.

Conventionally, there is provided a method for collectively forming, arranging and wiring the crystal oscillation circuit in one layer in the multi-layered substrata structure and removing all of corresponding portions of the other circuit patterns lying in the vertical surface of the area at another layer (for example, refer to Jpn. Pat. Appln. KOKAI Publication No. H10-22734).

However, with the above method, since the crystal oscillation circuit must be collectively formed, arranged and wired in one layer, it takes a long time and labor to manufacture the same. Further, it is required to change the design of the circuit pattern because a pattern extracting portion is provided for each wiring layer and the manufacturing cost will be raised.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a perspective view showing the laminated structure of a printed circuit board for a real-time clock IC according to one embodiment of this invention.

FIG. 2 is a plan view of the printed circuit board for a real-time clock IC as viewed from the side in the above embodiment.

FIG. 3A is a plan view of the wiring layer of the printed circuit board for a real-time clock IC as viewed from above in the above embodiment.

FIG. 3B is a plan view of the power supply layer of the printed circuit board for a real-time clock IC as viewed from above in the above embodiment.

FIG. 4 is a circuit diagram showing one example of the connection configuration of an oscillator circuit pattern and a real-time clock IC in the above embodiment.

FIG. 5 is a circuit diagram for illustrating the relation between the adjusting capacitance and stray capacitance in the above embodiment.

FIG. 6 is a block diagram when the printed circuit board for a real-time clock IC according to the above embodiment is applied to a timer of a key-telephone equipment.

### DETAILED DESCRIPTION

Various embodiments according to the invention will be described hereinafter with reference to the accompanying drawings. In general, according to one embodiment of the invention, a printed circuit board for a real-time clock IC comprising: a plurality of wiring layers sequentially laminated to form one substrata and including at least one layer which forms an oscillator circuit pattern having a crystal oscillator generating a reference signal and an oscillation stabilizing portion which stabilizes and oscillates the reference signal and adjusts the oscillation frequency to a target frequency, and a power supply layer or ground layer arranged in at least one of a position between the plurality of wiring layers and a position on one of front and rear surfaces of the substrata, and obtained by forming a power supply circuit pattern which supplies electric power to a circuit on the substrata and removing a portion of a power supply circuit pattern which has width not smaller than width of the oscillation circuit pattern in a portion of a power supply circuit pattern which overlaps with the oscillator circuit pattern, when the surface of the substrate is projected in a vertical direction at another layer. It is the same also about a grand pattern.

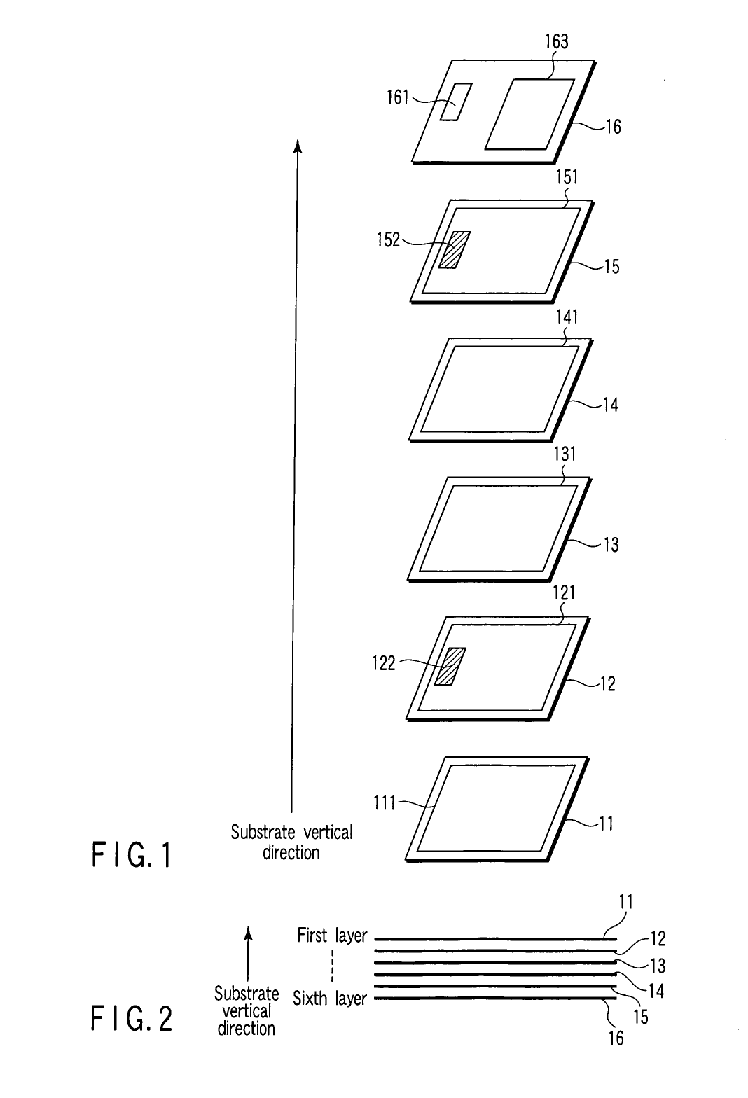

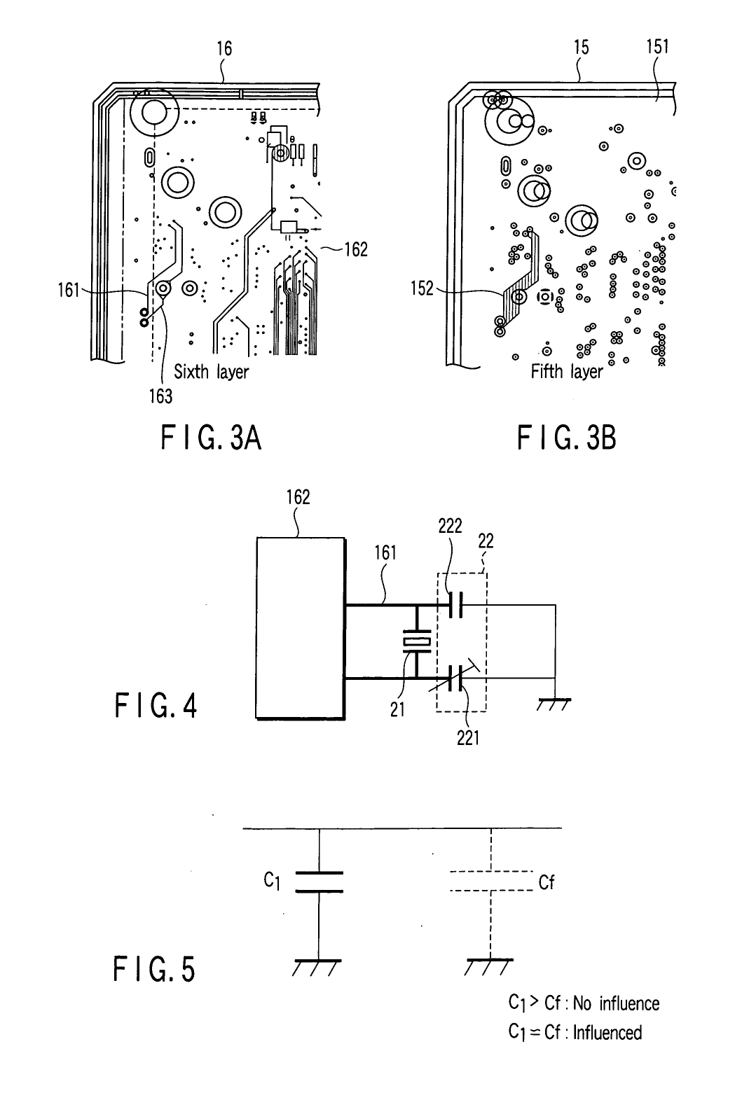

FIG. 1 is a perspective view showing the laminated structure of a printed circuit board for a real-time clock IC according to one embodiment of this invention, FIG. 2 is a plan view of the printed circuit board for the real-time clock IC shown in FIG. 1 as viewed from the side, FIG. 3A is a plan view of the wiring layer of the printed circuit board for a real-time clock IC as viewed from above, and FIG. 3B is a plan view of the power supply layer thereof as viewed from above. In this example, for brevity of the explanation, a six-layered structure is shown.

In FIG. 1, a reference symbol 11 denotes a wiring layer which forms a peripheral circuit pattern 111 of an integrated circuit (IC) formed of a copper foil surface, for example. On the upper surface of the wiring layer 11, a ground layer 12 is laminated. A wiring layer 13 having an IC peripheral circuit pattern 131 formed thereon is laminated on the upper surface of the ground layer 12 and a wiring layer 14 having an IC peripheral circuit pattern 141 formed thereon is laminated on the upper surface of the wiring layer 13.

A power supply layer 15 is laminated on the upper surface of the wiring layer 14 and a wiring layer 16 is laminated on the upper surface of the power supply layer 15. As shown in FIG. 3A, an oscillator circuit pattern 161 and IC pattern 163 are formed on the wiring layer 16. Further, as shown in FIG. 3B, a ground solid pattern 151 used as a power supply circuit pattern to supply electric power to the IC peripheral circuit patterns 111, 131, 141, oscillator circuit pattern 161 and real-time clock IC 162 is formed on the power supply layer 15. A pattern extracting portion 152 on which a copper foil surface is not formed is formed in a portion of the ground solid pattern 151 which overlaps with the oscillation circuit pattern 161 when it is projected in the substrate vertical direction at another layer. The pattern extracting portion 152 has the same width as or an area larger than the oscillator circuit pattern 161.

Further, a ground solid pattern 121 which lowers the electric power from the IC peripheral circuit patterns 111, 131, 141, oscillator circuit pattern 161 and real-time clock IC 162 to the ground power is formed on the upper surface of the ground layer 12. A pattern extracting portion 122 is formed in a portion of the ground solid pattern 121 which overlaps with the oscillator circuit pattern 161 when it is projected in the substrate vertical direction at another layer.

FIG. 4 shows one example of the connection configuration of the oscillator circuit pattern 161 and a real-time clock IC 162 configured together with a crystal oscillator 21 which generates a clock signal as a reference signal. An oscillator stabilizing circuit 22 having a trimmer capacitor 221 and fixed-capacitance capacitor 222 is connected to the crystal oscillator 21. The oscillation stabilizing circuit 22 activates the crystal oscillator 21 according to the capacitance adjusted by the trimmer capacitor 221 so as to cause the same to perform the oscillating operation. The real time clock IC 162 receives an oscillation output of the crystal oscillator 21 and performs a preset signal processing operation based on the oscillation output.

Next, the manufacturing process and frequency adjusting operation of the above configuration are explained.

The pattern extracting portions 122, 152 of the ground layer 12 and power supply layer 15 are formed in the manufacturing process for the printed circuit board for the real-time clock IC. In a state in which the pattern extracting portions 122, 152 are respectively formed on the ground layer 12 and power supply layer 15, the ground layer 12 is laminated on the upper surface of the wiring layer 11, the wiring layer 13 is laminated on the upper surface of the ground layer 12, and the wiring layer 14, power supply layer 15 and wiring layer 16 are sequentially formed on the upper surfaces of the wiring layer 13, wiring layer 14 and power supply layer 15, respectively.

In the printed circuit board for a real-time clock IC thus formed, it is required to adjust the capacitance of the trimmer capacitor 221 at the time of shipment of a product and set the oscillation frequency of a clock signal oscillated from the oscillator 21 to coincide with the center value of the target oscillation frequency so as to set the precision of a real-time clock into a preset specification. At this time, as shown in FIG. 5, it is necessary to take stray capacitance Cf into consideration in addition to the total capacitance C1 of the trimmer capacitor 221 and fixed-capacitance capacitor 222.

The stray capacitance Cf can be expressed by ε×S/d when the dielectric constant is ε, the area of the power supply layer 15 which overlaps with the wiring layer 16 when it is projected in the substrate vertical direction at another layer is set to S and a gap between the power supply layer 15 and the wiring layer 16 is set to d. As a result, in the printed circuit board with the multi-layered structure, the gap between the power supply layer 15 and the wiring layer 16 becomes small, the stray capacitance Cf becomes larger than the total capacitance C1 and the oscillation frequency of the crystal oscillator 21 cannot be set to coincide with the center value of the target oscillation frequency.

Therefore, in the present embodiment, S can be set to 0 by extracting a portion of the ground solid pattern 151 of the power supply layer 15 which overlaps with the oscillator circuit pattern 161 and, as a result, the stray capacitance can be reduced to as a small value as negligible.

The pattern extracting portion 152 is difficult to be influenced by disturbance if it has the same width as or an area larger than the oscillator circuit pattern 161.

As described above, in the present embodiment, the stray capacitance can be reduced to as a small value as negligible by forming the pattern extracting portion 152 obtained by removing a portion of the ground solid pattern 151 of the power supply layer 15 which has the same width as or an area larger than the oscillator circuit pattern 161 in a portion of the ground solid pattern 151 which overlaps with the oscillator circuit pattern 161 of the wiring pattern 16 when it is projected in the substrata vertical direction at another layer. Further, the pattern extracting portion 122 obtained by removing a portion of the ground solid pattern 121 of the ground layer 12 which has the same width as or an area larger than the oscillator circuit pattern 161 is formed in a portion of the ground solid pattern 121 of the ground layer 12 which overlaps with the oscillator circuit pattern 161 of the wiring pattern 16 when it is projected in the substrate vertical direction.

Therefore, the oscillation frequency of the clock signal oscillated from the crystal oscillator 21 can be set to coincide with the center value of the target oscillation frequency at high precision by use of the trimmer capacitor 221 as required by using the preset fixed-capacitance capacitor 222 irrespective of the way of forming the circuit pattern. Thus, the oscillation frequency can be adjusted with the high precision. Further, the number of manufacturing steps can be reduced in comparison with a case wherein the crystal oscillator circuit is collectively formed, arranged and wired in one layer like the conventional case.

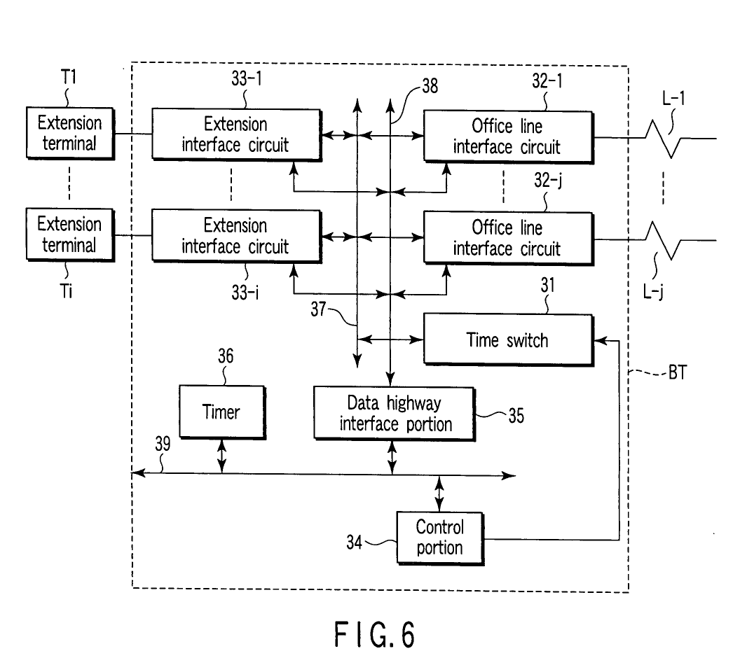

The printed circuit board for a real-time clock IC in the present embodiment can be applied to a timer 36 of a key telephone apparatus BT shown in FIG. 6. A plurality of (i at maximum) extension terminals T1 to Ti are connected to the key telephone apparatus BT.

The key telephone apparatus BT further includes a time switch 31, a plurality of (j) office line interface circuits 32 (32-1 to 32-j), a plurality of (i) extension interface circuits 33 (33-1 to 33-i), control portion 34 and data highway interface portion 35. The time switch 31, office line interface circuits 32 and extension interface circuits 33 are connected to one another via a PCM highway 37.

Further, the office line interface circuits 32, extension interface circuits 33 and data highway interface portion 35 are connected to one another via a data highway 38. Also, the control portion 34, data highway interface portion 35 and timer 36 are connected to one another via a CPU bus 39. The time switch 31 is directly connected to the control portion 34.

The time switch 31 freely and interchangeably connects the office line interface circuits 32 and extension interface circuits 33 by exchanging the time slots on the PCM highway 37 under control of the control portion 34.

Office lines L (L-1 to L-j) are connected to the office line interface circuits 32 as required. The office line interface circuits 32 perform the interface operations relating to the connected office lines L.

The extension terminals T1 to Ti are connected to the extension interface circuits 33 as required. The extension interface circuits 33 perform the extension interface operations associated with the connected extension terminals T1 to Ti.

The control portion 34 generally controls the time switch 31, office line interface circuits 32 and extension interface circuits 33 by performing the process based on a operation program previously stored and time information counted by the timer 36 to realize the operation of the key telephone apparatus BT.

The data highway interface portion 35 transfers data between the data highway 38 and the CPU bus 39.

The precision of a real-time clock of the required specification can be satisfied by applying the printed circuit board for a real-time clock IC according to the embodiment of this invention to the timer 36 of the key telephone apparatus BT.

In the present embodiment, a case wherein the oscillation frequency of the clock signal of the timer 36 of the key telephone apparatus BT is adjusted is explained. However, it is possible to apply this invention to an electronic apparatus such as an audio device or the like. In short, this invention can be applied to any device if it is an electronic apparatus having a real-time clock function.

In the present embodiment, a case wherein the ground layer 12 and power supply layer 15 are laminated is explained. However, it is possible to use only the power supply layer 15 or only the ground layer 12.

In addition, the type and the laminated structure of the printed circuit board for a real-time clock IC, the configuration of the oscillation stabilizer circuit, the method of forming the pattern extracting portion and the like can be variously modified without departing from the technical scope of this invention.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A printed circuit board for a real-time clock IC comprising:
a plurality of wiring layers sequentially laminated to form one substrata and including at least one layer which forms an oscillator circuit pattern having a crystal oscillator generating a reference signal and an oscillation stabilizing portion which stabilizes and oscillates the reference signal and adjusts the oscillation frequency to a target frequency, and
a power supply layer arranged in at least one of a position between the plurality of wiring layers and a position on one of front and rear surfaces of the substrate, and obtained by forming a power supply circuit pattern which supplies electric power to a circuit on the substrate and removing a portion of the power supply circuit pattern which has width not smaller than width of the oscillator circuit pattern in a portion of the power supply circuit pattern which overlaps with the oscillator circuit pattern, when the surface of the substrata is projected in a vertical direction at another layer.

2. The printed circuit board for a real-time clock IC according to claim 1, wherein the oscillation stabilizing portion includes at least one of a fixed-capacitance element and variable capacitance element.

3. The printed circuit board for a real-time clock IC according to claim 1, further comprising a ground layer arranged in at least one of a position between the plurality of wiring layers and a position on one of front and rear surfaces of the substrata and obtained by forming a ground circuit pattern which lowers electric power from the circuit on the substrate to ground power and removing a portion of the ground circuit pattern which has width not smaller than width of the oscillator circuit pattern in a portion of the ground circuit pattern which overlaps with the oscillator circuit pattern when the surface of the substrata is projected in a vertical direction at another layer.

4. A printed circuit board for a real-time clock IC comprising:
a plurality of wiring layers sequentially laminated to form one substrate and including at least one layer which forms an oscillator circuit pattern having a crystal oscillator generating a reference signal and an oscillation stabilizing portion which stabilizes and oscillates the reference signal and adjusts the oscillation frequency to a target frequency, and
a ground layer arranged in at least one of a position between the plurality of wiring layers and a position on one of front and rear surfaces of the substrata and obtained by forming a ground circuit pattern which lowers electric power from a circuit on the substrata to ground power and removing a portion of the ground circuit pattern which has width not smaller than width of the oscillator circuit pattern in a portion of the ground circuit pattern which overlaps with the oscillator circuit pattern when the surface of the substrata is projected in a vertical direction at another layer.

5. The printed circuit board for a real-time clock IC according to claim 4, wherein the oscillation stabilizing portion includes at least one of a fixed-capacitance element and variable capacitance element.

6. The printed circuit board for a real-time clock IC according to claim 1, further comprising a power supply layer arranged in at least one of a position between the plurality of wiring layers and a position on one of front and rear surfaces of the substrata and obtained by forming a power supply circuit pattern which supplies electric power to the circuit on the substrate and removing a portion of the power supply circuit pattern which has width not smaller than width of the oscillator circuit pattern in a portion of the power supply circuit pattern which overlaps with the oscillator circuit pattern, when the surface of the substrate is projected in a vertical direction at another layer.

7. A manufacturing method for a printed circuit board for a real-time clock IC which includes a plurality of wiring layers sequentially laminated to form one substrata and including at least one of layer which forms an oscillator circuit pattern having a crystal oscillator generating a reference signal and an oscillation stabilizing portion which stabilizes and oscillates the reference signal and adjusts a oscillation frequency to a target frequency, comprising:
preparing at least one of a power supply layer obtained by forming a power supply circuit pattern which supplies electric power to a circuit on the substrata and removing a portion of the power supply circuit pattern which has width not smaller than width of the oscillator circuit pattern in a portion of the power supply circuit pattern which overlaps with the oscillator circuit pattern when the surface of the substrata is projected in a vertical direction and a ground layer obtained by forming a ground circuit pattern which lowers electric power from the circuit on the substrate to ground power and removing a portion of the ground circuit pattern which has width not smaller than width of the oscillator circuit pattern in a portion of the ground circuit pattern which overlaps with the oscillator circuit pattern when the surface of the substrata is projected in a vertical direction, and
arranging at least one of the power supply layer and ground layer in one of a position between the plurality of wiring layers and a position on one of front and rear surfaces of the substrata.
